(19) United States
(12) Patent Application Publication
(10) Pub. No.: US 2005/0207462 A1
(43) Pub. Date: Sep. 22, 2005

(54) Semiconductor laser

(76) Inventors: Shinichi Agatsuma, Miyagi (JP); Shiro Uchida, Miyagi (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/053,430

(22) Filed: Feb. 8, 2005

(30) Foreign Application Priority Data
Feb. 17, 2004 (JP) P2004-040463

(51) Int. Cl. H01S 5/00

(52) U.S. Cl. 372/43.01

(57) ABSTRACT

A semiconductor laser is provided, of a configuration that is capable of correcting a difference between refractive indexes when an epitaxial growth is given in an irregular surface condition. A semiconductor laser is formed, which has a semiconductor laser element of a compound semiconductor containing at least Al and In, and having at least p-type cladding layers, an active layer, and an-type cladding layer, and has a configuration in which at least part of the p-type cladding layers have an Al composition in relatively larger amount as compared with an Al composition of the n-type cladding layer or at least part of the n-type cladding layer has an Al composition in relatively smaller amount as compared with the Al composition of the p-type cladding layers.

### CROSS REFERENCE TO RELATED APPLICATIONS

The present document is based on Japanese Priority Document JP2004-040463, filed to the Japanese Patent Office on Feb. 17, 2004, the contents of which being incorporated herein by reference.

### BACKGROUND OF THE INVENTION

1. Field of the Invention

The present invention relates to an AlGaInP-based semiconductor laser, and more particularly, to a semiconductor laser that is suitable to a case where an AlGaInP-based semiconductor laser element and a semiconductor laser element of different group are integrated to provide an integration of a plurality of semiconductor laser elements of different wavelengths.

2. Related Art

With an increasing versatility of optical recording media, apparatuses have been proposed capable of recording and reproducing different types of optical recording media, such as, for instance, two different types of disc including a CD (Compact Disc) and a DVD (Digital Versatile Disc).

A two-wavelength semiconductor laser formed by the integration of two semiconductor laser elements of different oscillation wavelength is used for a light source of an optical pickup of a recording and reproducing apparatus of the above type, which can be found in Japanese Patent Laid-open Application No. 2001-320131 and Japanese Patent Laid-open Application No. 2002-329934, for example.

For instance, the optical pickup of the recording and reproducing apparatus for recording and reproducing both the CD and the DVD described the above has, as a light source, a two-wavelength semiconductor laser having a semiconductor laser element having an oscillation wavelength of 780 nm for a recording and a reproduction of the CD, and a semiconductor laser element having an oscillation wavelength of 650 nm for the recording and the reproduction of the DVD.

In addition, an AlGaAs semiconductor laser element is used as the semiconductor laser element for the recording and the reproduction of the CD, while an AlGaInP-based semiconductor laser element is used as the semiconductor laser element for the recording and the reproduction of the DVD.

Generally, the two-wavelength semiconductor laser composed of the AlGaAs semiconductor laser element and the AlGaInP-based semiconductor laser element described the above is fabricated through processes shown in FIG. 5A to FIG. 8D, for example. Incidentally, in FIGS. 5A to 8D, layers in the form of a multi-layered arrangement of a cladding layer and an active layer etc. of each semiconductor laser element are shown altogether as epitaxial layers.

Firstly, as shown in FIG. 5A, after an epitaxial layer 22 contained in the AlGaAs (which is hereinafter referred to as a three-element) semiconductor laser element is grown on a substrate 21, a resist 23 for a patterning of a three-element epitaxial layer 22 is formed on the three-element epitaxial layer.

Then, as shown in FIG. 5B, the three-element epitaxial layer 22 in the right side of the Figure is removed by etching through the resist 23 serving as a mask.

Subsequently, as shown in FIG. 5C, after an AlGaInP-based (which is hereinafter referred to as a four-element) epitaxial layer 24 is grown, a resist 25 for the patterning of the four-element epitaxial layer 24 is formed on the four-element epitaxial layer 24. The resist 25 is supposed to be formed except a center portion of the four-element epitaxial layer 24 in the right side of the Figure.

Then, as shown in FIG. 5D, the four-element epitaxial layer 24 at a left side and a center side is removed by the etching through the resist 25 serving as the mask.

Then, as shown in FIG. 6A, a SiO₂ film 26 is formed to cover a surface using a CVD process, for instance.

Subsequently, as shown in FIG. 6B, a resist 27 is formed on the SiO₂ film 26 for formation of a stripe.

Next, as shown in FIG. 6C, the SiO₂ film 26 other than a stripe portion is removed by an isotropic etching such as a wet etching through the resist 27 serving as the mask. This allows the SiO₂ film 26 of a width narrower than that of the resist 27 to remain.

Then, a denaturing film 28 is formed to cover the surface, and the patterning of the denaturing film 28 takes place to ensure that the denaturing film 28 is allowed to remain, with the resist 27 covered. Further, as shown in FIG. 6D, a resist 29 is formed to cover part of the four-element epitaxial layer 24 at the right side.

Next, an ion implantation of impurities takes place. At this time, the resists 27 and 29 serve as the mask, so that an ion-doped region 30 is formed at the opposite sides of the SiO₂ film 26 on the surface of the three-element epitaxial layer 22 at the left side, as shown in FIG. 7A.

Then, the resists 27 and 29 are removed. The denaturing film 28 is also removed when the removal of the resist 27 takes place, which allows only the SiO₂ film 26 to remain. Further, as shown in FIG. 7B, a resist 31 is formed to cover the three-element epitaxial layer 22 at the left side.

Then, a stripe of a ridge structure is formed by the etching of the four-element epitaxial layer 24 through the resist 31 and the SiO₂ film 26 serving as the mask, as shown in FIG. 7C.

Subsequently, the resist 31 is removed, as shown in FIG. 7D.

Then, as shown in FIG. 8A, a (third) epitaxial layer 32 including n-type GaAs, for instance, is grown on the surface. At this time, a growth of the epitaxial layer 32 does not occur in a portion where the surface is covered with the SiO₂ film 26.

Then, as shown in FIG. 8B, a resist 33 is formed, and the epitaxial layer 32 at the center side, in other words, at a portion between the two laser elements is removed with the resist 33 serving as the mask.

Then, the resist 33 covering the three-element epitaxial layer 22 of the left side is removed and only the resist 33 covering over the four-element epitaxial layer at the right side is left. Then, as shown in FIG. 8C, the epitaxial layer 32 remaining on the three-element epitaxial layer 22 at the left side is removed by etching with the remaining resist 33 serving as a mask.

Next, the resist 33 is removed, and further, the SiO₂ film 26 is removed by stripping, whereby the two-wavelength semiconductor laser having, on the identical substrate, two semiconductor laser elements 41, 42 maybe fabricated as shown in FIG. 8D.

### SUMMARY OF THE INVENTION

In the above mentioned fabrication process, when the AlGaInP-based (four-element) epitaxial layer 24 is grown, part of the earlier formed AlGaAs (three-element) epitaxial layer 22, in other words, a region for the formation of the AlGaInP-based (four-element) semiconductor laser element undergoes an etch-off, so that an irregular surface condition may be obtained.

An epitaxial growth of an AlGaInP-based (four-element) material, if being given in the irregular surface condition as described the above, brings about the following differences compared to the case where the epitaxial growth is given on a flat substrate.

A first difference is that a film thickness of the four-element epitaxial layer 24 is made smaller.

A second difference is that an In composition increases more than a prescribed composition, leading to a lattice mismatching with the substrate.

These phenomena are supposed to occur for a reason in that Al and Ga among source materials available for the four-element material have greater migration length than In.

It may be appreciated from FIG. 9, showing a relation between the In composition and a refractive index (cited from Pages 33 to 35 of [Semiconductor Laser] edited by Applied Physical Society and published by Ohmsha, Ltd.) that the refractive index varies with a size of the In composition, so that an increase in the In composition results in an increase in the refractive index.

Particularly, the increase in the In composition occurs more remarkably in the p-type cladding layer than in the n-type cladding layer.

For this reason, when the stripe of the ridge structure is formed as shown in FIG. 8D, a ridge portion provides the refractive index higher than a prescribed refractive index, resulting in a problem in that An (a difference between a refractive index n1 of the stripe portion and a refractive index n2 of a portion other than the stripe portion), an important design parameter, automatically increases.

An increase in the parameter An as described the above brings about harmful effects such as an occurrence of a kink due to no attainment of a cutoff in a higher order mode and an increase in a FFP (Far Field Pattern) due to an intensified optical confinement in a horizontal direction.

For instance, a method of reducing the In composition simply by reducing an amount of In in the source gas for use in a film deposition is supposed to be applicable to a correction of the increasing In composition.

However, in the process of growing the four-element epitaxial layer 24 (FIG. 5B), a monitor wafer whose surface is flat is placed normally in an identical deposition apparatus for the purpose of confirming a condition of deposition of the four-element epitaxial layer 24.

Then, reducing the amount of In in the source gas for use in the film deposition causes a hatch pattern (a lattice defect) to be contained in a monitor wafer substrate, resulting in no attainment of a role as the monitor wafer. This is because the hatch pattern is obtained more easily in a portion having an In composition in relatively small amount than a portion having an In composition in relatively large amount.

No attainment of the role as the monitor wafer as described the above may result in no confirmation as to whether or not the four-element epitaxial layer 24 is deposited properly in a prescribed manner.

In addition, the above problem is supposed to arise not only when fabricating the two-wavelength semiconductor laser containing the AlGaInP-based semiconductor laser element but also when forming the epitaxial layer of the AlGaInP-based semiconductor laser element on an irregular surface portion.

In view of the above mentioned problems, the present invention is intended to provide a semiconductor laser having a configuration that is capable of correcting a difference between refractive indexes in the case where the epitaxial growth is given in an irregular surface condition.

A semiconductor laser according to a preferred embodiment of the present invention has a semiconductor laser element including a compound semiconductor at least containing Al and In, wherein the semiconductor laser element is composed of at least a p-type cladding layer, an active layer, and a p-type cladding layer, and is given a configuration in which at least part of the p-type cladding layer has an Al composition in relatively larger amount as compared with an Al composition of the n-type cladding layer, or at least part of the n-type cladding layer has an Al composition in relatively smaller amount as compared with the Al composition of the p-type cladding layer.

In other words, the composition of AlGaInP, when expressed as AlₓGa₁₋ₓInP, for instance, is set to satisfy a relation of Xn<Xp≦1.0 or 0≦Xn<Xp, where a value of the Al composition X of at least part of the n-type cladding layer is assumed to be Xn, and a value of the Al composition X of at least part of the p-type cladding layer is assumed to be Xp.

According to the configuration of the semiconductor laser according to a preferred embodiment of the present invention described the above, there is provided the configuration in which at least part of the p-type cladding layer has the Al composition in relatively larger amount as compared with the Al composition of the n-type cladding layer or at least part of the n-type cladding layer has the Al composition in relatively smaller amount as compared with the Al composition of the p-type cladding layer, whereby the cladding layer having the large amount of Al composition is supposed to provide a small refractive index, resulting in a reduction in the refractive index at the side of the p-type cladding layer having relatively large Al composition.

This may enable the semiconductor laser element having the prescribed Δn to be obtained through a correction of a refractive index portion that increases with the increase in the In composition of the p-type cladding layer at the time of fabrication.

Alternatively, according to a preferred embodiment of the present invention, a semiconductor laser element is provided including a compound semiconductor at least containing Al and In, wherein the semiconductor laser element is composed of at least a p-type cladding layer, an active layer, and a p-type cladding layer, in which either at least part of the p-type cladding layer has a composition of Al in relatively larger amount as compared to an Al composition of the n-type cladding layer, and at least part of the p-type cladding layer has a composition of In in relatively larger amount as compared to the In composition of the n-type cladding layer, or at least part of the n-type cladding layer has a composition of Al in relatively smaller amount as compared to the Al composition of the p-type cladding layer, and at least part of the n-type cladding layer has a composition of In in relatively smaller amount as compared to the In composition of the p-type cladding layer.

The semiconductor laser according to another preferred embodiment of the present invention may have, on an identical substrate, a plurality of semiconductor laser elements for providing an oscillation of laser beams having different wavelengths, wherein the plurality of semiconductor laser elements include a first semiconductor laser element that is specified as a semiconductor laser element including a compound semiconductor at least containing Al and In, and the first semiconductor element is composed of at least a p-type cladding layer, an active layer, and a n-type cladding layer, and is given a configuration in which at least part of the p-type cladding layer in the first semiconductor laser element may have a large Al composition in relatively smaller amount as compared with an Al composition of the n-type cladding layer, or at least part of the n-type cladding layer may have a small Al composition in relatively smaller amount as compared with the Al composition of the p-type cladding layer.

According to the configuration of the semiconductor laser according to a preferred embodiment of the present invention described the above, there is provided a configuration in which at least part of the p-type cladding layer in the first semiconductor laser element may have an Al composition in relatively smaller amount as compared with the Al composition of the n-type cladding layer or at least part of the n-type cladding layer may have the Al composition in relatively smaller amount as compared with the Al composition of the p-type cladding layer, whereby the cladding layer having the large Al composition is supposed to provide a smaller refractive index, resulting in the reduction in the refractive index at the side of the p-type cladding layer having relatively large Al composition.

This may enable the correction of the refractive index portion that increases with the increase in the In composition of the p-type cladding layer of the first semiconductor laser element in the case where a growth of an epitaxial layer of the first semiconductor laser element is given on an irregular surface obtained after a patterning of an earlier formed epitaxial layer of a different semiconductor laser element, for instance, at the time of the fabrication, whereby the first semiconductor laser element may be given the configuration having the prescribed Δn.

According to a preferred embodiment of the present invention, an action that causes the refractive index to increase with the increase in the In composition of the p-type cladding layer may be particularly restrained in the case where the growth of the epitaxial layer of the semiconductor laser element including the compound semiconductor at least containing Al and In is given on the irregular surface when fabricating the semiconductor laser.

The correction of the difference between the refractive indexes may be easily performed without need to vary the amount of In in the source material.

This may enable the prescribed an to be obtained with the refractive index of the p-type cladding layer as the prescribed refractive index, leading to a realization of a semiconductor laser that ensures satisfactory characteristics involving no occurrence of the kink caused by the higher order mode, and an attainment of a satisfactory-shaped FFP.

Further, since there is no need to vary the amount of In in the source material, when a monitor wafer with flat surface is used to confirm the condition of deposition of the epitaxial layer of the semiconductor laser element including the compound semiconductor at least containing Al and In, the confirmation of the condition of deposition may be carried out without creating any hatch pattern (a lattice defect) in the monitor wafer.

Then, in the case of the formation of the semiconductor laser composed of the plurality of semiconductor laser elements including the first semiconductor laser element including the compound semiconductor at least containing Al and In, and the different semiconductor laser element of different oscillation wavelength, the prescribed Δn may be obtained through the correction of the difference between the refractive indexes of the first semiconductor laser element, particularly, the p-type cladding layers, when the growth of the epitaxial layer of the first semiconductor laser element is given on the irregular surface obtained after the patterning of the earlier formed epitaxial layer of the different semiconductor laser element, leading to the realization of the semiconductor laser composed of the plurality of semiconductor laser elements of different oscillation wavelength, wherein these semiconductor laser elements provide the satisfactory characteristics.

### BRIEF DESCRIPTION OF THE DRAWINGS

The above and other objects, features and advantages of the present invention will become more apparent from the following description of the presently preferred exemplary embodiments of the invention taken in conjunction with the accompanying drawings, in which:

FIG. 1 is a view showing an Al composition distribution in a direction of a multi-layered arrangement of an epitaxial layer in an AlGaInP-based semiconductor laser element according to a preferred embodiment of the present invention;

FIG. 2 is a view showing a relation between composition of an Al and a refractive index for AlGaInP;

FIG. 3 is a view showing comparison of an output change against a current change in a two-wavelength semiconductor laser, wherein FIG. 3A shows a case where a general AlGaInP-based semiconductor laser element is used, while FIG. 3B shows a case where the AlGaInP-based semiconductor laser element of the configuration shown in FIG. 1 is used;

FIG. 4 is a view showing the Al composition distribution in the direction of the multi-layered arrangement of an epitaxial layer in the general AlGaInP-based semiconductor laser element;

FIGS. 5A to 5D are views showing processes of a general fabrication method of a two-wavelength semiconductor laser;

FIGS. 6A to 6D are views showing processes of the general fabrication method of the two-wavelength semiconductor laser;

FIGS. 7A to 7D are views showing processes of the general fabrication method of the two-wavelength semiconductor laser;

FIGS. 8A to 8D are views showing processes of the general fabrication method of the two-wavelength semiconductor laser; and

FIG. 9 is a view showing a relation between an In composition of AlGaInP and the refractive index.

### DESCRIPTION OF THE PREFERRED EMBODIMENTS

A configuration of a general AlGaInP-based semiconductor laser element is firstly described before a description of a configuration of a preferred embodiment of the present invention.

The general AlGaInP-based semiconductor laser element is formed by a multi-layered arrangement of an n-type AlGaInP cladding layer, an active layer, and a p-type AlGaInP cladding layer through a buffer layer on a substrate. Further, there is provided a guide layer between the active layer and each cladding layer, as needed.

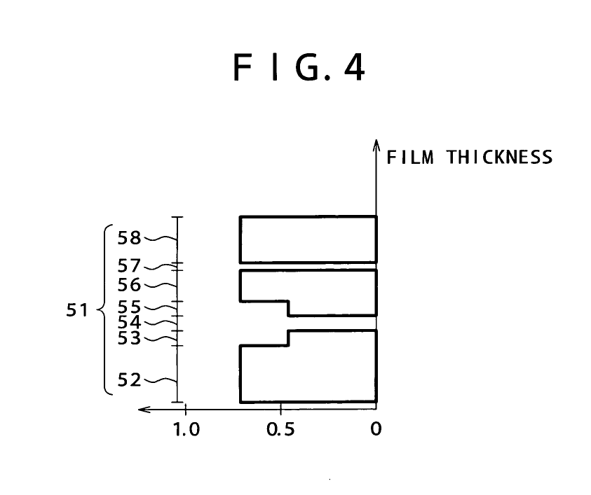

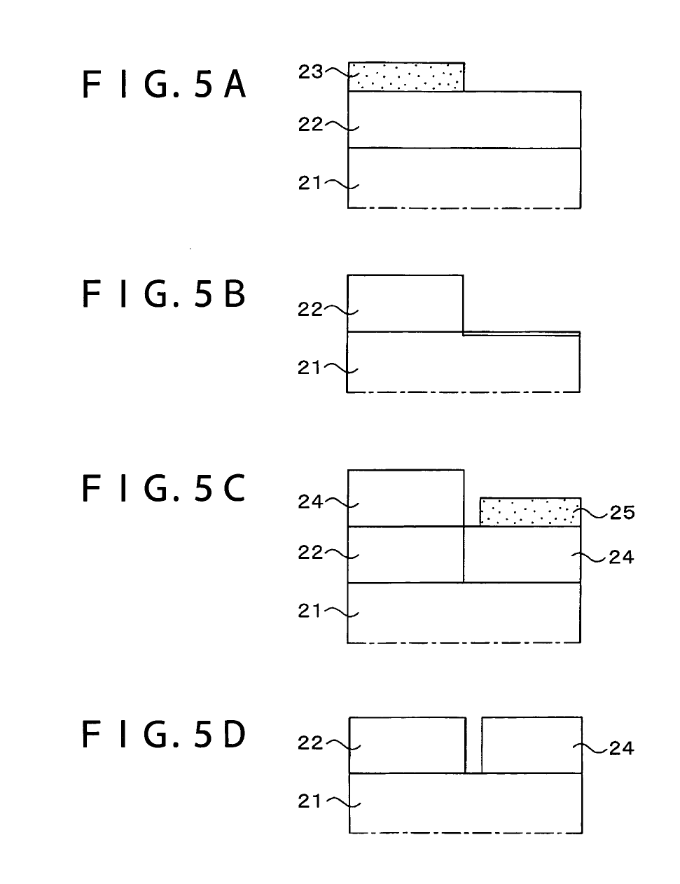

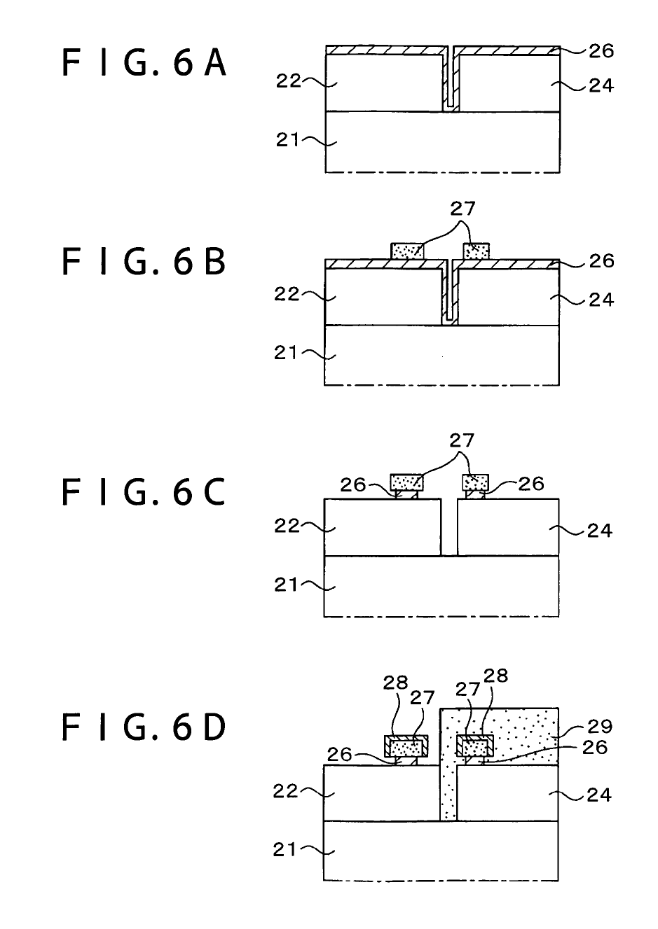

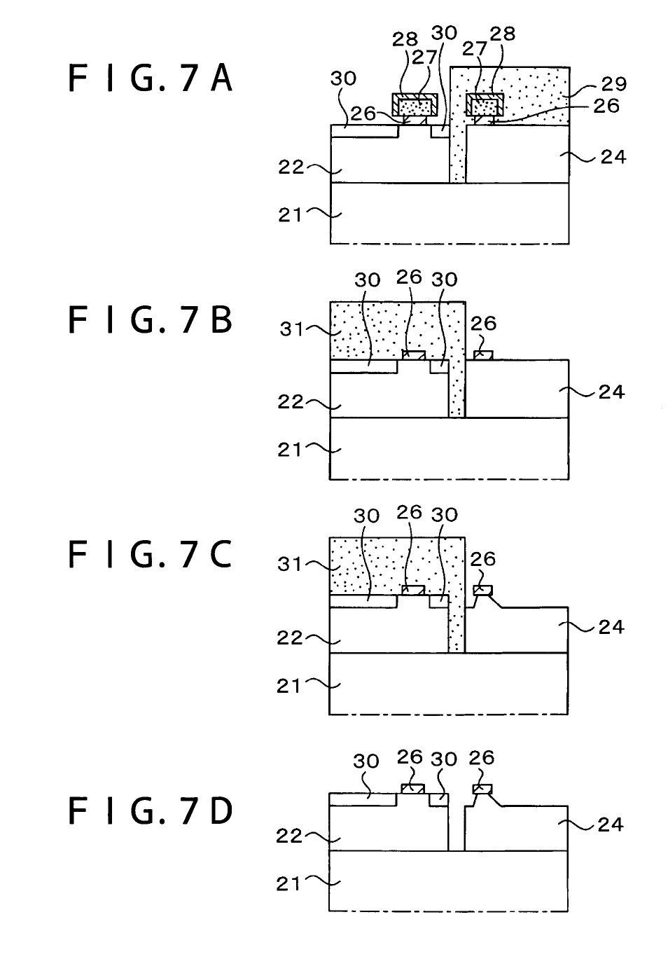

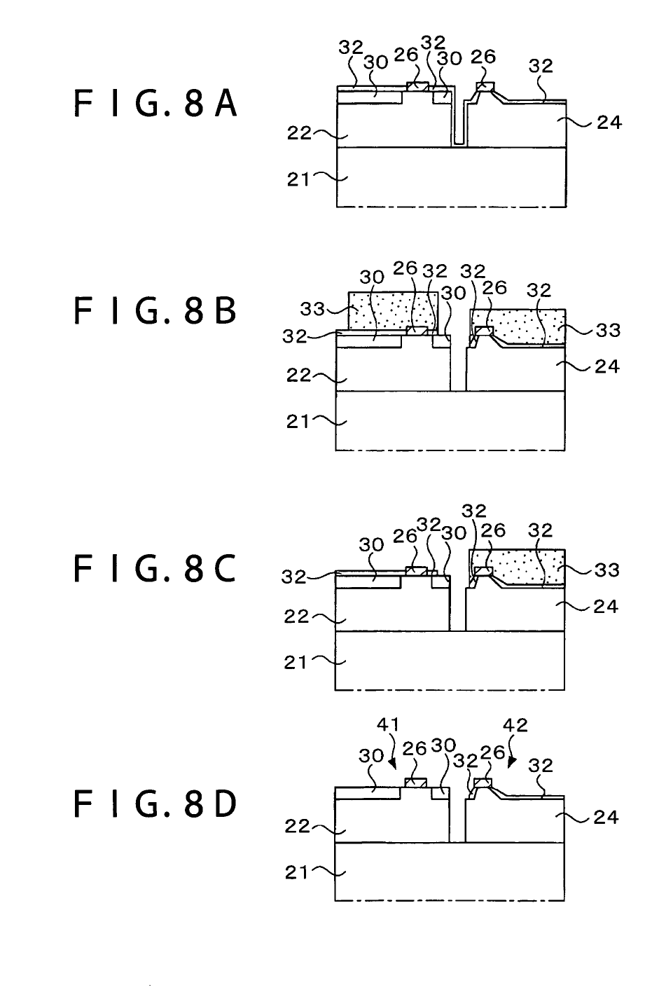

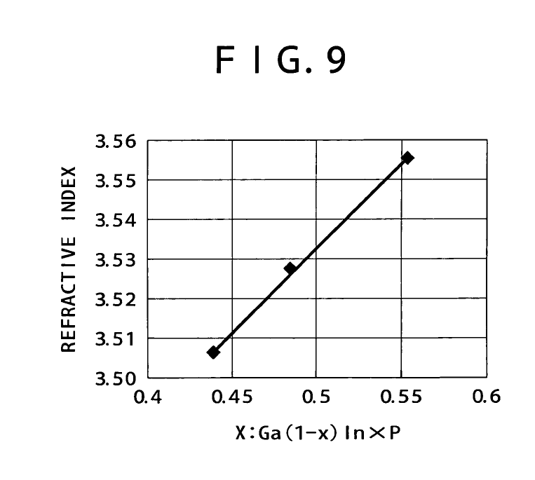

FIG. 4 shows a distribution of Al composition in a direction of the multi-layered arrangement of an epitaxial layer in a general AlGaInP-based semiconductor laser element.

An epitaxial layer 51 of the AlGaInP-based semiconductor laser element is formed by the multi-layered arrangement of a n-type cladding layer 52, a guide layer 53, an active layer 54, a guide layer 55, a second p-type cladding layer 56, an etching stop layer 57, and a first p-type cladding layer 58.

In addition, an Al composition is supposed to be the same (about 0.7 in each case) in the first p-type cladding layer 58, the second p-type cladding layer 56, and the n-type cladding layer 52.

A configuration of an AlGaInP-based semiconductor laser element as a preferred embodiment of the present invention is now described.

The embodiment of the present invention is supposed to reduce the Al composition of the n-type cladding layer in the AlGaInP-based semiconductor laser element more than that of the p-type cladding layer.

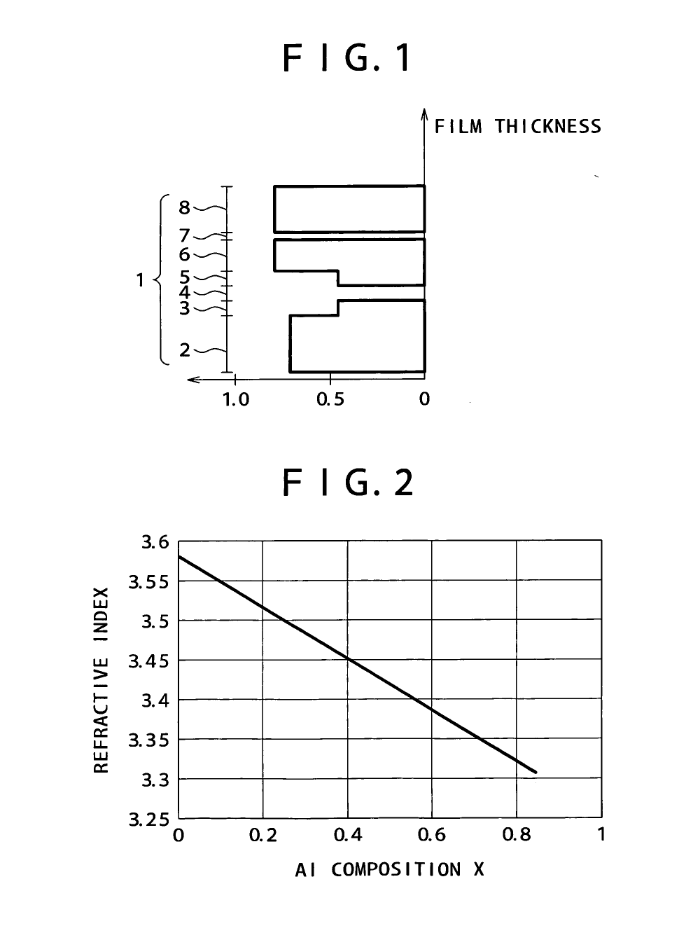

FIG. 1 shows the Al composition distribution in the direction of the multi-layered arrangement of the epitaxial layer in the AlGaInP-based semiconductor laser element of the preferred embodiment of the present invention.

An epitaxial layer 1 of the AlGaInP-based semiconductor laser element is formed by the multi-layered arrangement of a n-type cladding layer 2, a guide layer 3, an active layer 4, a guide layer 5, a second p-type cladding layer 6, an etching stop layer 7, and a first p-type cladding layer 8.

As shown in FIG. 1, the embodiment of the present invention provides the first and the second p-type cladding layers 8 and 6 in the form of layers that have an Al composition of larger amount than the general AlGaInP-based semiconductor laser element shown in FIG. 4, whereby the first and the second p-type cladding layers 8 and 6 are supposed to have the Al composition in larger amount than that the n-type cladding layer 2.

AlGaInP has a property of causing the refractive index to reduce as the Al composition increases.

FIG. 2 shows a change of refractive index for a composition of (AlₓGa₁₋ₓ)_{0.51}In_{0.49}P, for instance, when the Al composition X has changed,

It may be appreciated from FIG. 2 that the refractive index decreases as the Al composition X increases, so that the change of the refractive index occurs in the form of a linear change.

As a result, an increase in the Al composition of the first and the second p-type cladding layers 8 and 6 may cause the refractive index in the first and the second p-type cladding layers 8 and 6 to reduce.

This may enable the p-type cladding layers 8 and 6 to have the prescribed refractive index in such a manner that the refractive index that increases with increasing In composition remarkably easily caused in the p-type cladding layers 8 and 6 in particular is corrected by the refractive index that reduces with increasing Al composition.

In other words, an occurrence of the kink caused by the higher order mode and an extent of the FFP may be restrained through a restraint of An from increasing with the increase in the refractive index in the p-type cladding layers 8 and 6.

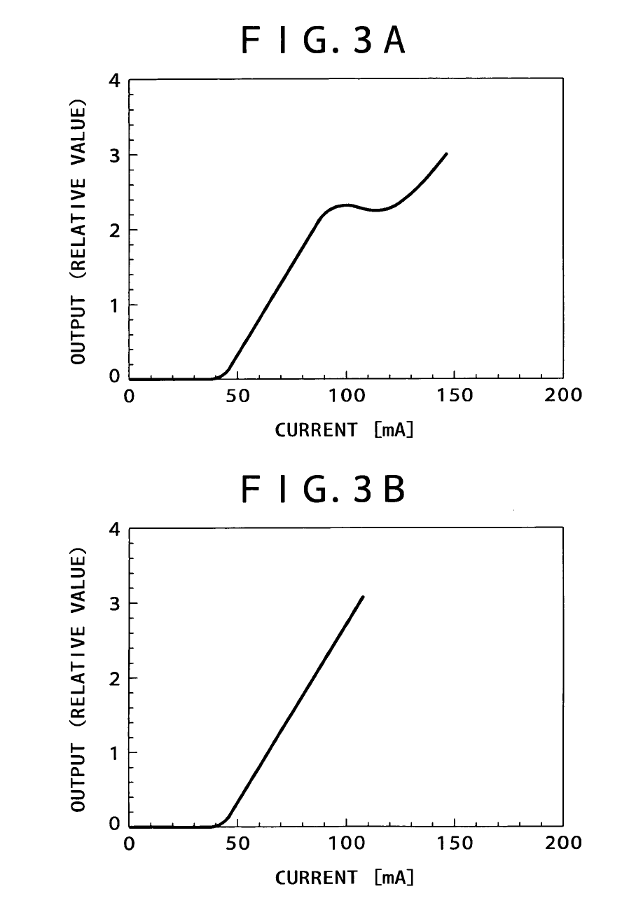

FIGS. 3A and 3B show an output change to a current change by a comparison in the two-wavelength semiconductor laser including the AlGaAs semiconductor laser element and the AlGaInP-based semiconductor laser element. FIG. 3A shows the case where the general AlGaInP-based semiconductor laser element is used, while FIG. 3B shows the case where the AlGaInP-based semiconductor laser element of the embodiment of the present invention is used. In FIGS. 3A and 3B, a horizontal axis indicates a current [mA], and a vertical axis indicates an output (a relative value).

It may be appreciated from FIG. 3A that in the case of the use of the general AlGaInP-based semiconductor laser element having the p-type cladding layer and the n-type cladding layer that are equal in the Al composition, a bent-shaped output change is obtained when a current is increased, resulting in the occurrence of the so-called kink.

Conversely, it may be appreciated from FIG. 3B that in the case of the use of the AlGaInP-based semiconductor laser element of the embodiment of the present invention, an approximately uniform increase in the output is obtained with an increase in the current, resulting in no occurrence of the kink.

The fabrication of the semiconductor laser element of the configuration of the preferred embodiment of the present invention, in other words, the configuration in which the first and the second p-type cladding layers 8 and 6 have the Al composition in larger amount than that of the general semiconductor laser element may be attained by merely increasing an amount of Al in the source gas for use in the deposition of the first and the second p-type cladding layers 8 and 6, for instance.

Then, a setting of how much the Al composition of the p-type cladding layers 8 and 6 is increased is merely needed depending on a degree of the correction of the refractive index in the p-type cladding layers 8 and 6.

According to the above configuration of the embodiment of the present invention, the first and the second p-type cladding layers 8 and 6 are supposed to have the Al composition in larger amount than that of the n-type cladding layer 2, resulting in the reduction in the refractive index in the first and the second p-type cladding layers 8 and 6.

This may enable the restraint of the action that causes the refractive index to increase with the increase in the In composition, in the case where the growth of the epitaxial layer of the AlGaInP-based semiconductor laser element is given on the irregular surface when fabricating the semiconductor laser, for example.

As a result, the correction of the difference between the refractive indexes in the AlGaInP-based semiconductor laser element may be easily performed without need to vary the amount of In in the source material.

This may enable the predetermined An to be obtained with the refractive index in the p-type cladding layers 8 and 6 as the prescribed refractive index, leading to the realization of the semiconductor laser that ensures the satisfactory characteristics involving no occurrence of the kink caused by the higher order mode, and the attainment of the satisfactory-shaped FFP.

Then, an application of the configuration of the AlGaInP-based semiconductor laser element according to the embodiment of the present invention to the two-wavelength semiconductor laser composed of the AlGaInP-based semiconductor laser element and the different semiconductor laser element of different oscillation wavelength may result in the realization of the two-wavelength semiconductor laser of desirable characteristics.

Further, there is no need to vary the amount of In in the source material, so that when the monitor wafer whose surface is flat is used to confirm the condition of deposition of the AlGaInP-based (four-element) epitaxial layer, the confirmation of the condition of deposition may be carried out without creating any hatch pattern (the lattice defect) in the monitor wafer.

By the way, the epitaxial layer of the AlGaInP-based semiconductor laser element is not limited to the layered arrangement shown in FIG. 1, and the present invention may adopt various layered arrangements other than the above.

While the above embodiment of the present invention allows the Al composition of the whole p-type cladding layers 8 and 6 to be increased more than that of the n-type cladding layer, the present invention may be also modified to allow the Al composition of only part of the p-type cladding layer to be increased more than that of the n-type cladding layer. For instance, it is also allowable to form the p-type cladding layer by the multi-layered arrangement of a portion having the Al composition in larger amount than that of the n-type cladding layer, and a portion having the same Al composition as the n-type cladding layer.

Furthermore, in this case, the portion having the Al composition in larger amount may be formed at any of an upper part, a center part or a lower part of the p-type cladding layer.

Further, the present invention may be also modified to allow the Al composition of at least part of the n-type cladding layer to be reduced more than that of the p-type cladding layer.

In this case, the reduction in the Al composition of the n-type cladding layer may result in the increase in the refractive index in the n-type cladding layer.

This allows the refractive index in the p-type cladding layer to be relatively reduced more than the refractive index in the n-type cladding layer, enabling the prescribed An to be obtained by the restraint of the increase in An through the correction of the increase in the refractive index in the p-type cladding layer with the increase in the In composition, like the case where the Al composition of the p-type cladding layer is increased.

Thus, a semiconductor laser may be realized with satisfactory characteristics, like the case where the Al composition of the p-type cladding layer is increased.

Incidentally, as far as any semiconductor laser element including the compound semiconductor containing Al and In is given without being limited to the AlGaInP-based semiconductor laser element, the benefits of the present invention may be obtained likewise.

The present invention is not limited to the above mentioned preferred embodiments, and it is to be understood that various configurations other than the above are possible without departing from the spirit and scope of the present invention.

1. A semiconductor laser including a semiconductor laser element made of a compound semiconductor containing at least Al and In, wherein
at least a p-type cladding layer, an active layer, and a n-type cladding layer are formed on the semiconductor laser element; and
either at least part of the p-type cladding layer has a composition of Al in relatively larger amount as compared to the Al composition of the n-type cladding layer, or
at least part of the n-type cladding layer has a composition of Al in relatively smaller amount as compared to the Al composition of the p-type cladding layer.

2. A semiconductor laser including a semiconductor laser element made of a compound semiconductor containing at least Al and In, wherein
at least a p-type cladding layer, an active layer, and a n-type cladding layer are formed on the semiconductor laser element; and
either at least part of the p-type cladding layer has a composition of Al in relatively larger amount as compared to an Al composition of the n-type cladding layer, and at least part of the p-type cladding layer has a composition of In in relatively larger amount as compared to the In composition of the n-type cladding layer, or
at least part of the n-type cladding layer has a composition of Al in relatively smaller amount as compared to the Al composition of the p-type cladding layer, and at least part of the n-type cladding layer has a composition of In in relatively smaller amount as compared to the In composition of the p-type cladding layer.

3. The semiconductor laser according to claim 1, wherein the semiconductor laser element is an AlGaInP-based semiconductor laser element.

4. A semiconductor laser having a plurality of semiconductor laser elements capable of oscillating laser beams of different wavelengths formed on a same substrate, wherein:
a first semiconductor laser element among the plurality of semiconductor laser elements includes a semiconductor laser element made of a compound semiconductor containing at least Al and In;
at least a p-type cladding layer, an active layer, and a n-type cladding layer are formed on the first semiconductor laser element; and
either at least part of the p-type cladding layer in the first semiconductor laser element has a composition of Al in relatively larger amount as compared to the Al composition of the n-type cladding layer, or
at least part of the n-type cladding layer has a composition of Al in relatively smaller amount as compared to the Al composition of the p-type cladding layer.

5. The semiconductor laser according to claim 4, wherein, in the first semiconductor laser element, either
at least part of the p-type cladding layer has a composition of Al in relatively larger amount as compared to an Al composition of the n-type cladding layer, and at least part of the p-type cladding layer has a composition of In in relatively larger amount as compared to the In composition of the n-type cladding layer, or
at least part of the n-type cladding layer has a composition of Al in relatively smaller amount as compared to the Al composition of the p-type cladding layer, and at least part of the n-type cladding layer has a composition of In in relatively smaller amount as compared to the In composition of the p-type cladding layer.

6. The semiconductor laser according to claim 4, wherein the first semiconductor laser element is an AlGaInP-based semiconductor laser element.
